(19) United States
(12) Patent Application Publication
(10) Pub. No.: US 2008/0151676 A1
(43) Pub. Date: Jun. 26, 2008

(54) Semiconductor integrated circuit

(75) Inventor: Yosuke Mizutani, Hashima-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., MORIGUCHI-SHI (JP); SANYO SEMICONDUCTOR CO., LTD., ORA-GUN (JP)

(21) Appl. No.: 12/000,629

(22) Filed: Dec. 14, 2007

(30) Foreign Application Priority Data
Dec. 20, 2006 (JP) 2006-342433

(51) Int. Cl. G11C 5/14

(52) U.S. Cl. 365/229

(57) ABSTRACT

A semiconductor integrated circuit in which a semiconductor chip 4 having a semiconductor memory and a mother chip 2 having logic circuit are mounted in a single package, wherein the leak current of the semiconductor chip 4 is reduced in standby state. A switch cell 20 that connects to the power pad 10 of the semiconductor chip 4 and that supplies power voltage from the exterior to the semiconductor chip 4 is provided to the mother chip 2. The switch cell 20 cuts off the connection between the power pad 10 of the semiconductor chip 4 and the power voltage line of the semiconductor memory of the mother chip 2 by using a control signal from a control circuit when the semiconductor memory is in standby mode. Leak current generated in the semiconductor memory can thereby be reduced.

### CROSS-REFERENCE TO RELATED APPLICATION

The priority application number JP2006-342433 upon which this patent application is based is hereby incorporated by the reference.

### BACKGROUND OF THE INVENTION

1. Field of the Invention

The present invention relates to power supply control of a semiconductor integrated circuit, and particularly relates to power supply control of a semiconductor integrated circuit wherein a semiconductor chip in which a semiconductor memory is formed and a semiconductor chip in which a logic circuit is formed are mounted in the same package.

2. Description of the Related Art

The degree of integration of a semiconductor integrated circuit improves every year, and multifunction semiconductor integrated circuits are being developed by integrating circuits that have a variety of functions into a single semiconductor chip. So-called multi-chip packages (MCP) have come into practice in which a separate semiconductor chip (referred to in the present specification as a “stacked chip”) is mounted on a semiconductor chip (referred to in the present specification as “mother chip”) in order to achieve a semiconductor integrated circuit that has a greater number of functions. A semiconductor integrated circuit in which a plurality of semiconductor chips have been mounted in a single package in this manner is referred to as a multi-chip module. This multi-chip module reduces the mounting surface area by superimposing chips having completely different functions, and the cost of manufacturing products in which such modules are mounted can be brought down by reducing the number of chips that are mounted on a substrate.

A typical applied example of a multi-chip module is one in which a DRAM (dynamic random access memory), i.e., a stacked chip for storing data used by the circuit, is mounted on a mother chip in which analog and digital arithmetic circuits are combined or in which a control circuit for controlling specific equipment is formed. With a multi-chip module in which a DRAM chip is mounted on a mother chip, the power voltage, e.g., high voltage (VDD) and low voltage (VSS), required to operate the DRAM chip is supplied to the DRAM chip from the exterior via the mother chip.

A technique related to a multi-chip module in which a DRAM chip is mounted on a mother chip is disclosed in Japanese Laid-open Patent Publication No. 2002-100729, for example.

With a conventional semiconductor integrated circuit in which a DRAM chip is mounted by superimposition on a mother chip, the power voltage (VDD, VSS) required to operate the DRAM chip is supplied to the DRAM chip even when the DRAM chip is in a non-access state (standby mode), i.e., when there is no data exchange between the mother chip and the DRAM chip. As a result, a problem arises in the standby mode in that leak current occurs between the VDD and VSS inside the DRAM chip, and the power consumption of the DRAM chip increases.

### SUMMARY OF THE INVENTION

The present invention provides a cutoff circuit that stops the supply of power voltage from one semiconductor chip to another semiconductor chip in a semiconductor integrated circuit in which a plurality of semiconductor chips are mounted in a single package.

In accordance with the present invention, leak current inside the DRAM chip in standby mode, for example, can be reduced and the power consumption of the semiconductor integrated circuit can be reduced.

### BRIEF DESCRIPTION OF THE DRAWINGS

FIG. 1 is a plan view of a semiconductor integrated circuit in an MCP configuration according to an embodiment of the present invention;

FIG. 2 is a cross-sectional view of a semiconductor integrated circuit in an MCP configuration according to an embodiment of the present invention; and

FIG. 3 is a cross-sectional view of a semiconductor integrated circuit in an MCP configuration according to an embodiment of the present invention.

### DESCRIPTION OF THE PREFERRED EMBODIMENTS

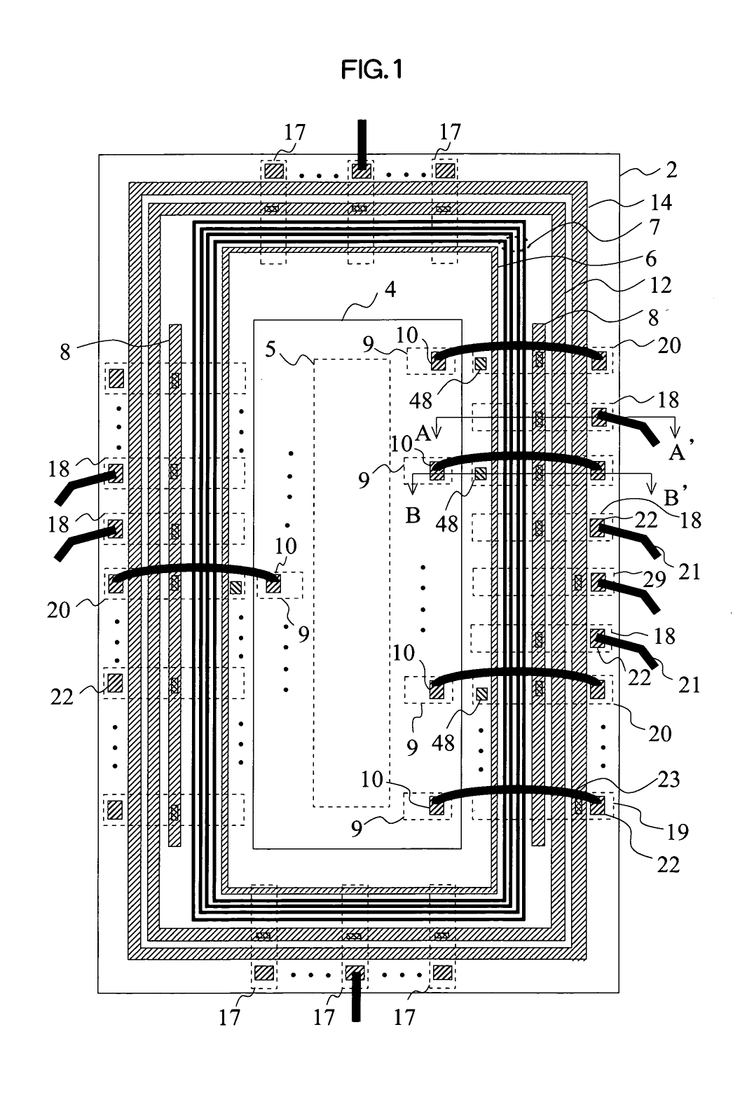

FIG. 1 is a plan view of a semiconductor integrated circuit in which a DRAM chip 4 is mounted in an MCP configuration on a mother chip 2 in which a logic circuit is formed. The DRAM chip 4 is arranged in the center area of the mother chip 2. The DRAM chip 4 has numerous storage elements that each store a single bit of digital data and that are formed in the form of a grid in the center area of the chip, and constitutes a storage unit 5. A high voltage (VDD_DRAM) and a low voltage (VSS_DRAM) for expressing digital data composed of O's and 1's i.e., binary values, are supplied to the storage unit 5. For example, the digital data “0” corresponds to VSS_DRAM, and “1” corresponds to VDD_DRAM. VDD_DRAM and VSS_DRAM are supplied from the exterior via I/O (Input/Output) cells 9 disposed in the vicinity of the storage unit 5 on the DRAM chip 4. Here, the I/O cells 9 are formed only in the long-side sections of the DRAM chip 4.

On the mother chip 2 in the vicinity of the DRAM chip 4, a plurality of power lines is disposed so as to surround the DRAM chip 4. A first power line 6 for supplying a first power voltage (VDD1) to the logic circuit or the like of the mother chip 2 is formed in a position adjacent to the DRAM chip 4. VDD1 can be set to about 1.5 V, for example.

A plurality of power lines 7 (Vdd, Vss) for pre-buffering circuits is formed in the vicinity of the first power line 6. A pre-buffer is composed of a level shifter or the like for amplifying or reducing the voltage supplied from the exterior.

A DRAM power line 8 for supplying VDD_DRAM to the DRAM chip 4 is formed in the vicinity of the plurality of power lines 7 for pre-buffers, on the long-side section of the mother chip 2. In this case, the plurality of I/O cells 9 of the DRAM chip 4 is arrayed along the long sides of the DRAM chip 4. Therefore, the DRAM power pads 10 of the I/O cells 9 for supplying VDD_DRAM are disposed on the long sides of the mother chip 2 and are not required to be disposed on the short sides. The DRAM power line 8 is therefore advantageously disposed in the long-side sections of the mother chip 2, and the DRAM power line 8 is not required to be disposed in the short-side sections of the mother chip 2.

A second power line 12 for supplying a second power voltage (VDD2) to the logic circuit or the like of the mother chip 2 is formed in the vicinity of the DRAM power line 8. Here, VDD2 can be set to a higher voltage than that of VDD1 and can be set to about 1.65 to 3.3 V.

A GND line 14 set to ground voltage is formed in the vicinity of the second voltage line 12. The GND line 14 is also formed in the shape of a ring so as to surround the DRAM chip 4.

The voltage applied to the first power line 6 and the power lines 7 for pre-buffers is lower than the voltage applied to the DRAM power line 8. Therefore, the line width of the first power line 6 and the power lines 7 may be less than that of the DRAM power line 8.

A plurality of I/O cells that extend in the direction orthogonal to the plurality of power lines and allow the mother chip 2 to exchange signals with the exterior of the chip is formed in the long- and short-side sections of the mother chip 2. The plurality of I/O cells provided to the long-side section of the mother chip 2 is composed of first I/O cells 18 for supplying a VDD_DRAM from the exterior of the chip to the DRAM power line 8 of the mother chip 2, second I/O cells 20 for presenting the DRAM chip 4 with a VDD_DRAM supplied from the exterior of the chip, an I/O cell 29 for supplying a VSS_DRAM from the exterior of the chip to the mother chip 2, and a I/O cell 19 for supplying a VSS_DRAM to the DRAM chip 4. As particularly used in the present specification, the first I/O cells 18 shall be referred to as “external cells 18,” the I/O cell 19 shall be referred to as “ground cell 19,” and the second I/O cells 20 shall be referred to as “switch cells 20.” A plurality of I/O cells 17 connected to the second power line 12 is provided to the short-side sections of the mother chip 2. Although not shown in FIG. 1, an I/O cell for supplying the externally applied VDD1 and VDD2 to the first power line 6 and second power line 12 of the mother chip 2 is also provided to the long-side section of the mother chip 2. On the other hand, the external cells 18 and switch cells 20 are not provided to the short-side section. This is because the external cells 18 and the switch cells 20 are connected to the DRAM power line 8 disposed in the long-side sections of the mother chip 2.

The I/O cells on the mother chip 2 are formed so as to intersect with the plurality of power lines, but a DRAM power line 8 is provided to the long-side sections of the mother chip 2, and the DRAM power line 8 is not provided to the short-side sections. Therefore, the length of the I/O cells in the direction orthogonal to the power line is different in the long- and short-side sections. In other words, the I/O cells 17 disposed in the short-side sections is shorter than the external cells 18 and switch cells 20 disposed in the long-side sections of the mother chip 2. The longitudinal dimension of the mother chip 2 can thereby be reduced and the chip surface area of the mother chip 2 can be made smaller.

Bonding pads 22 are formed on the external cells 18 and the switch cells 20. The bonding pads 22 of the external cells 18 are used for connecting the mother chip 2 to the exterior of the mother chip 2. The bonding pads 22 of the switch cell 20 are used for connecting the mother chip 2 with the DRAM chip 4. The bonding pads 22 are disposed in the outermost section of the mother chip 2, i.e., further outside of the plurality of power lines. The bonding pads 22 of the external cells 18 are connected by wires 21 to the exterior of the chip, and the bonding pads 22 of the switch cells 20 are connected by wires 23 to the power pads 10 on the DRAM chip 4. In other words, the wires 23 are formed so as to straddle the plurality of power lines.

Control pads 48 described below are provided to the switch cells 20. The control pads 48 are advantageously formed on the same layer as the plurality of power lines.

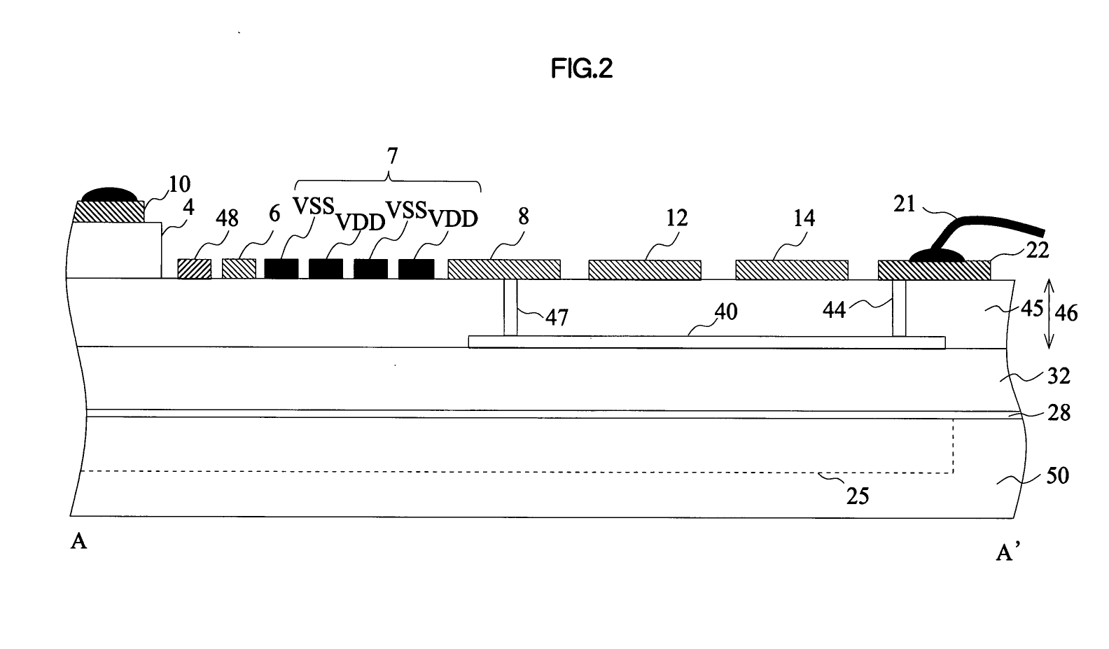

FIG. 2 is a cross-sectional view of one of the external cells 18 along the line A-A′ of FIG. 1. An arithmetic circuit composed of various logic circuits, or another semiconductor integrated circuit 25 is formed in the vicinity of the surface of the semiconductor substrate 50 of the mother chip 2. A wiring layer 46 composed of an insulation film 45 and wiring 40 that is composed of Al or the like is formed on the semiconductor chip 50 via an insulation layer. The insulation film 45 serves to electrically insulate the wiring 40 and the plurality of power lines formed on the wiring layer 46. The wiring layer 46 of FIG. 2 has a structure in which only a single layer of wiring is formed, but the present invention is not limited to this structure, and the wiring layer 46 may be a multilayered wiring structure composed of a plurality of layers of wiring.

The DRAM power line 8 and other power lines are formed on the wiring layer 46. The wiring 40 is connected to a bonding pad 22 and the DRAM power line 8 via contact holes 44 and 47. VDD_DRAM is supplied to the bonding pad 22 from the exterior of the chip via a wire 21, and VDD-DRAM is also supplied to the DRAM power line 8 via the wiring 40. VDD_DRAM is preferably supplied to the DRAM power line 8 by using a plurality of external cells 18 rather than a single external cell 18. This is because supply from a plurality of external cells 18 can make the voltage of the DRAM power line 8 more stable. In the present embodiment, for example, power supply is provided from five external cells 18, as shown in FIG. 1.

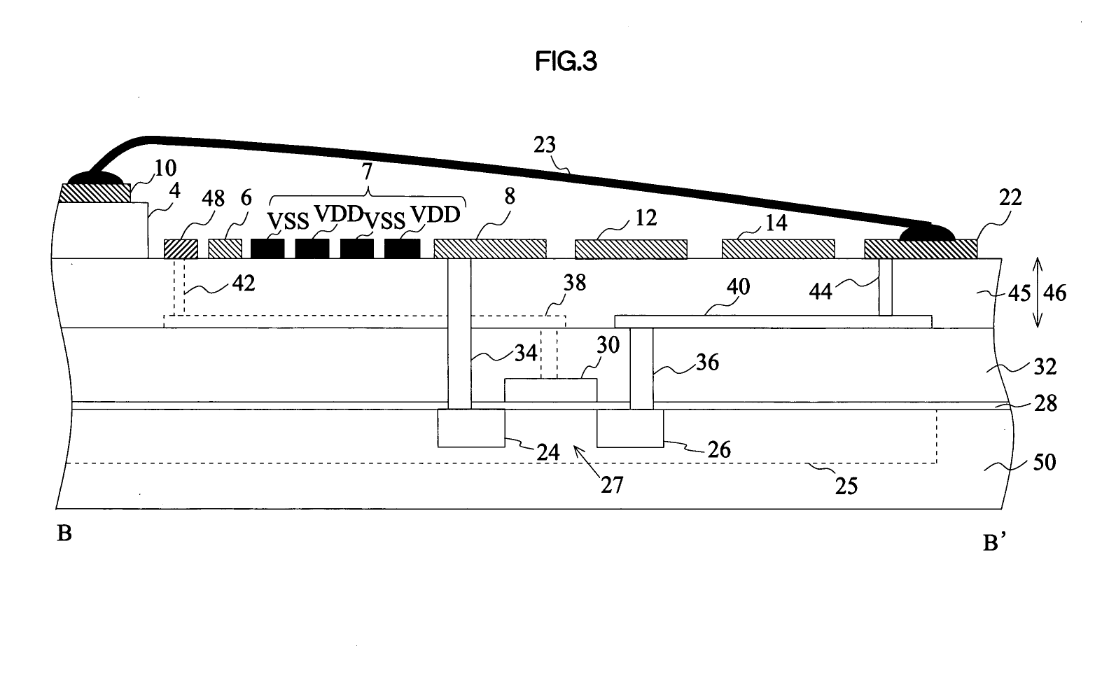

FIG. 3 shows a cross-sectional view of one of the switch cells 20 along the line B-B′ of FIG. 1. A semiconductor integrated circuit 25 such as an arithmetic circuit composed of various logic circuits is formed in the vicinity of the surface of a semiconductor substrate 50. A switch element 27 composed of a MOS transistor is provided as a part of a semiconductor integrated circuit 25, as shown in FIG. 3. The switch element 27 is preferably composed of a p-MOS transistor. Specifically, in a preferred configuration of the switch element 27, a source region 24 and drain region 26 doped with a high-concentration of a p-type are provided to the vicinity of the surface of the semiconductor substrate 50 composed of n-type silicon, and a gate electrode 30 is provided via a gate insulation layer 28.

Rather than a single switch element 27, a plurality of switch elements 27 is preferably provided to each switch cell 20 in a line in the direction in which the DRAM power line 8 extends. The electric current drive capacity can thereby be improved.

The wiring layer 46 is formed via an insulation film 32 on the semiconductor substrate 50 on which the semiconductor integrated circuit 25 including the switch element 27 is formed. The wiring layer 46 is composed of the wiring 40 and the insulation film 45. The wiring 40 is formed from aluminum, is connected to the drain region 26 of the switch element 27 via a contact hole 36, for example, and is connected via a contact hole to a bonding pad 22 disposed on the wiring layer 46. Specifically, the wiring 40 serves to electrically connect the drain region 26 and the bonding pad 22. The bonding pad 22 is electrically connected by wire bonding to the DRAM power pad 10 of the DRAM chip 4.

Wiring 38 serves to electrically connect the gate electrode 30 of the switch element 27 and the control pad 48 for supplying a signal that controls the on/off state of the switch element 27. A control signal is supplied to the control pad 48 from a control circuit (not shown) provided to the mother chip 2.

The source region 24 of the switch element 27 is connected to the DRAM power line 8 via a contact hole 34 that passes through the insulation film 32 and the wiring layer 46. A VDD_DRAM is supplied from the exterior of the chip to the DRAM power line 8 via an external cell 18. Therefore, the electric potential of the source region 24 is the VDD_DRAM.

In such a configuration, the VDD_DRAM supplied from the exterior of the chip to the DRAM power line 8 via the external cell 18 is supplied from the bonding pad 22 to the DRAM power pad 10 of the DRAM chip 4 via the switch element 27 when a control signal that switches the switch element 27 on is supplied from the control circuit to the gate electrode 30 of the switch element 27. On the other hand, when a control signal that switches the switch element 27 off is applied to the gate electrode 30, the connection between the DRAM power line 8 and the bonding pad 22 of the DRAM cell 20 is cut off, and the supply of the VDD_DRAM to the DRAM chip 4 is cut off as well.

In the present invention, the control signal that switches the switch element 27 off is supplied and the electrical connection between the DRAM power line 8 and the bonding pad 22 of the DRAM cell 20 is cut off in the standby mode in which the DRAM chip 4 is not accessed. Specifically, the VDD_DRAM is not supplied to the DRAM chip 4 during standby mode, and leak current can be prevented from occurring inside the DRAM. The power consumption of the DRAM can thereby be reduced.

The present invention is not limited to the embodiment described above. For example, in the embodiment described above, a plurality of power lines are disposed from the inside of the mother chip 2 in the sequence of the first power line 6, the power lines 7 for pre-buffers, the DRAM power line 8, and other components, but the arrangement order of the power lines can be arbitrarily set. The switch element is composed of a p-MOS transistor in the embodiment described above, but the switch element may instead be composed of an n-MOS transistor.

With the semiconductor integrated circuit of the present embodiment, a DRAM chip 4 is mounted on a mother chip 2 as a stacked chip by MCP configuration, but the stacked chip in the present invention is not limited to a DRAM chip 4 and may be any semiconductor chip in which power voltage is supplied from the exterior via the mother chip 2. In other words, the connection between the power lines that supply power voltage to the semiconductor chip and the power pads on the semiconductor chip is cut off by a switch element provided to the mother chip, whereby leak current generated in the semiconductor chip can be reduced in a state in which the semiconductor chip on the mother chip is not accessed.

In the present invention, a preferred configuration is one in which the number of switch cells 20 for supplying a VDD_DRAM to the DRAM chip 4 is greater than the number of external cells 18 for supplying a VDD_DRAM from the exterior of the chip to the mother chip 2.

External cells 18 and switch cells 20 for transferring power voltage to the DRAM chip 4 are provided to the long-side sections of the mother chip 2, and these cells are not provided to the short-side sections. The number of pins that extend from the short-side section of the mother chip 2 to the exterior of the chip can made to be less than the number of pins that extend from the long-side section to the exterior of the chip.

What is claimed is:

1. A semiconductor integrated circuit in which a plurality of semiconductor chips are mounted in a single package, the circuit comprising:
a cutoff circuit that stops the supply of power voltage from one of the semiconductor chips to another of the semiconductor chip.

2. The semiconductor integrated circuit of claim 1, wherein the plurality of semiconductor chips include a first semiconductor chip in which a logic circuit is formed, and a second semiconductor chip in which a semiconductor memory is formed.

3. The semiconductor integrated circuit of claim 2, wherein the cutoff circuit is a switch element composed of an MOS transistor, and the switch element cuts off the supply of power voltage from the first semiconductor chip to the second semiconductor chip in a standby mode in accordance with a control signal from a power control circuit provided to the first semiconductor chip.

4. A semiconductor integrated circuit, comprising:
a first semiconductor chip having a first I/O cell group composed of a plurality of I/O cells, and a second I/O cell group composed of a plurality of I/O cells; and
a second semiconductor chip which has a third I/O cell group composed of a plurality of I/O cells, and which is mounted on the first semiconductor chip, wherein
the first I/O cell group is used for connecting to an external circuit;
the second I/O cell group and the third I/O cell group are electrically connected; and
a cutoff circuit for cutting off the electrical connection with the third I/O cell group is provided to the second I/O cell group.

5. The semiconductor integrated circuit of claim 4, wherein
a power line for supplying power voltage to the second semiconductor chip is provided to the first semiconductor chip;
the first I/O cell group supplies to the power line the power voltage supplied from the external circuit;
the second I/O cell group supplies the power voltage to the third I/O cell group; and
the cutoff circuit is provided to each cell of the second I/O cell group and cuts off the power voltage supplied from the second I/O cell group to the third I/O cell group in standby mode.
